(19) United States
(12) Patent Application Publication
(10) Pub. No.: US 2024/0247010 A1
(43) Pub. Date: Jul. 25, 2024

(54) CYCLOSILAZANE PRECURSORS AND RELATED METHODS

(71) Applicant: ENTEGRIS, INC., Billerica, MA (US)

(72) Inventors: DaHye Kim, Suwon-si (KR); YeRim Yeon, Suwon-si (KR); SangJin Lee, Suwon-si (KR); MinSeok Ryu, Namdong-gu (KR); SeongCheol Kim, Suwon-si (KR)

(21) Appl. No.: 18/412,997

(22) Filed: Jan. 15, 2024

Related U.S. Application Data
(60) Provisional application No. 63/439,331, filed on Jan. 17, 2023.

(51) Int. Cl. C07F 7/21

(52) U.S. Cl. CPC C07F 7/21

(57) ABSTRACT

Precursors and related methods are provided. A precursor comprises a cyclosilazane compound. The cyclosilazane compound is a reaction product of an aminosilane and a halosilane. A method for forming the precursor comprises obtaining an aminosilane, obtaining a halosilane, and contacting the aminosilane and the halosilane to obtain the precursor. A method for forming a silicon-containing film using the precursor is also provided, among other embodiments.

### CROSS-REFERENCE TO RELATED APPLICATIONS

This application claims the benefit under 35 USC 119 of U.S. Provisional Patent Application No. 63/439,331, filed Jan. 17, 2023, the disclosure of which is hereby incorporated herein by reference in its entirety.

### FIELD

The present disclosure relates to cyclosilazane precursors for vapor deposition processes and related methods.

### BACKGROUND

Film formation on substrate surface is useful in semiconductor fabrication. Some films are formed on the substrate surface by vapor deposition processes. The vapor deposition processes use precursors.

### SUMMARY

Some embodiments of the present disclosure relate to a precursor comprising a compound of the formula:

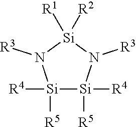

where:
R¹, R², R³, R⁴, and R⁵ are each independently a hydrogen, a linear alkyl, a branched alkyl, or a cycloalkyl, provided that R⁴ and R⁵ are not both hydrogen;
wherein the compound is a reaction product of:

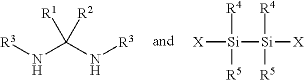

wherein:
R¹, R², R³, R⁴, and R⁵ are as defined above; and
X is Cl, Br, I, or F.

Some embodiments relate to a method for forming a precursor, the method comprising one or more of the following steps:
obtaining an aminosilane, wherein the aminosilane is a compound of the formula:

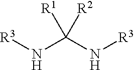

where:
R¹, R², and R³ are each independently a hydrogen, a linear alkyl, a branched alkyl, or a cycloalkyl;
obtaining a halosilane, wherein the halosilane is a compound of the formula:

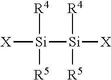

where:
X is Cl, Br, I, or F;
R⁴ and R⁵ are each independently a hydrogen, a linear alkyl, a branched alkyl, or a cycloalkyl, provided that R⁴ and R⁵ are not both hydrogen; and
contacting the aminosilane and the halosilane to form a precursor of the formula:

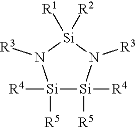

where:
R¹, R², R³, R⁴, and R⁵ are as defined above.

Some embodiments relate to a method for forming a silicon-containing film, the method comprising one or more of the following steps:
obtaining a precursor; wherein the precursor comprises a compound of the formula:

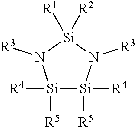

where:

R¹, R², R³, R⁴, and R⁵ are each independently a hydrogen, a linear alkyl, a branched alkyl, or a cycloalkyl, provided that R⁴ and R⁵ are not both hydrogen;
obtaining at least one co-reactant precursor;
vaporizing the precursor to obtain a vaporized precursor;
vaporizing the at least one co-reactant precursor to obtain at least one vaporized co-reactant precursor; and
contacting at least one of the vaporized precursor, the at least one vaporized co-reactant precursor, or any combination thereof, with a substrate, under vapor deposition conditions, to form a silicon-containing film on the substrate.

### DRAWINGS

Some embodiments of the disclosure are herein described, by way of example only, with reference to the accompanying drawings. With specific reference now to the drawings in detail, it is stressed that the embodiments shown are by way of example and for purposes of illustrative discussion of embodiments of the disclosure. In this regard, the description taken with the drawings makes apparent to those skilled in the art how embodiments of the disclosure may be practiced.

FIG. 1 is a flowchart of a method for forming a precursor, according to some embodiments.

FIG. 2 is a flowchart of a method for making a silicon-containing film, according to some embodiments.

FIG. 3 depicts a reaction scheme for forming a precursor, according to some embodiments.

FIG. 4 depicts a reaction scheme for forming a precursor, according to some embodiments.

FIG. 5 is a ¹H NMR spectrum of the 2,2,4,4,5,5-Hexamethyl-1,3-dipropyl-1,3,2,4,5-diazatrisilolidine product, according to some embodiments.

FIG. 6 is a ¹H NMR spectrum of the 2,2,4,4,5,5-Hexamethyl-1,3-diisopropyl-1,3,2,4,5-diazatrisilolidine product, according to some embodiments.

### DETAILED DESCRIPTION

Among those benefits and improvements that have been disclosed, other objects and advantages of this disclosure will become apparent from the following description taken in conjunction with the accompanying figures. Detailed embodiments of the present disclosure are disclosed herein; however, it is to be understood that the disclosed embodiments are merely illustrative of the disclosure that may be embodied in various forms. In addition, each of the examples given regarding the various embodiments of the disclosure which are intended to be illustrative, and not restrictive.

Any prior patents and publications referenced herein are incorporated by reference in their entireties.

Throughout the specification and claims, the following terms take the meanings explicitly associated herein, unless the context clearly dictates otherwise. The phrases “in one embodiment,” “in an embodiment,” and “in some embodiments” as used herein do not necessarily refer to the same embodiment(s), though it may. Furthermore, the phrases “in another embodiment” and “in some other embodiments” as used herein do not necessarily refer to a different embodiment, although it may. All embodiments of the disclosure are intended to be combinable without departing from the scope or spirit of the disclosure.

As used herein, the term “based on” is not exclusive and allows for being based on additional factors not described, unless the context clearly dictates otherwise. In addition, throughout the specification, the meaning of “a,” “an,” and “the” include plural references. The meaning of “in” includes “in” and “on.”

As used herein, the term “alkyl” refers to a hydrocarbon compound having from 1 to 30 carbon atoms. An alkyl having n carbon atoms may be designated as a “Cₙ alkyl.” For example, a “C₃ alkyl” may include n-propyl and isopropyl. An alkyl having a range of carbon atoms, such as 1 to 30 carbon atoms, may be designated as a C₁-C₃₀ alkyl. In some embodiments, the alkyl is substituted. In some embodiments, the alkyl is unsubstituted. In some embodiments, the alkyl comprises at least one of a C₁-C₁₀ alkyl, a C₁-C₉ alkyl, a C₁-C₈ alkyl, a C₁-C₇ alkyl, a C₁-C₆ alkyl, a C₁-C₅ alkyl, a C₁-C₄ alkyl, a C₁-C₈ alkyl, a C₂-C₁₀ alkyl, a C₅-C₁₀ alkyl, a C₄-C₁₀ alkyl, a C₅-C₁₀ alkyl, a C₆-C₁₀ alkyl, a C₇-C₁₀ alkyl, a C₈-C₁₀ alkyl, a C₂-C₉ alkyl, a C₂-C₈ alkyl, a C₂-C₇ alkyl, a C₂-C₆ alkyl, a C₂-C₅ alkyl, a C₃-C₈alkyl, a C₃-C₁₀ alkyl, a C₃-C₉ alkyl, a C₃-C₈ alkyl, a C₃-C₇ alkyl, a C₃-C₆ alkyl, a C₃-C₅ alkyl, a C₃-C₄ alkyl, or any combination thereof.

In some embodiments, the alkyl comprises at least one of a linear alkyl, a branched alkyl, or any combination thereof. Non-limiting examples of linear alkyls include at least one of a linear C₁-C₁₀ alkyl, a linear C₁-C₉ alkyl, a linear C₁-C₈ alkyl, a linear C₁-C₇ alkyl, a linear C₁-C₆ alkyl, a linear C₁-C₅ alkyl, a linear C₁-C₄ alkyl, a linear C₁-C₃ alkyl, a linear C₂-C₁₀ alkyl, a linear C₃-C₁₀ alkyl, a linear C₄-C₁₀ alkyl, a linear C₅-C₁₀ alkyl, a linear C₆-C₁₀ alkyl, a linear C₇-C₁₀ alkyl, a linear C₈-C₁₀ alkyl, a linear C₂-C₉ alkyl, a linear C₂-C₈ alkyl, a linear C₂-C₇ alkyl, a linear C₂-C₆ alkyl, a linear C₂-C₅ alkyl, a linear C₃-C₅ alkyl, a linear C₃-C₁₀ alkyl, a linear C₃-C₉ alkyl, a linear C₃-C₈ alkyl, a linear C₃-C₇ alkyl, a linear C₃-C₆ alkyl, a linear C₃-C₅ alkyl, a linear C₃-C₄ alkyl, or any combination thereof. Non-limiting examples of branched alkyls include at least one of a branched C₃-C₅ alkyl, a branched C₃-C₁₀ alkyl, a branched C₃-C₉ alkyl, a branched C₃-C₈ alkyl, a branched C₃-C₇ alkyl, a branched C₃-C₆ alkyl, a branched C₃-C₅ alkyl, a branched C₃-C₄ alkyl, or any combination thereof.

In some embodiments, the alkyl comprises at least one of methyl, ethyl, n-propyl, 1-methylethyl (iso-propyl), n-butyl, iso-butyl, sec-butyl, n-pentyl, 1,1-dimethylethyl (t-butyl), n-pentyl, iso-pentyl, n-hexyl, isohexyl, 3-methylhexyl, 2-methylhexyl, heptyl, octyl, nonyl, decyl, dodecyl, octadecyl, or any combination thereof. In some embodiments,

As used herein, the term “cycloalkyl” refers to a non-aromatic carbocyclic ring attached via a single bond and having 3 to 8 carbon atoms in the ring. The term includes a monocyclic non-aromatic carbocyclic ring and a polycyclic non-aromatic carbocyclic ring. For example, two or more cycloalkyls may be fused, bridged, or fused and bridged to obtain the polycyclic non-aromatic carbocyclic ring. In some embodiments, the cycloalkyl may comprise at least one of cyclopropyl, cyclobutyl, cyclopentyl, cyclohexyl, cycloheptyl, cyclooctyl, or any combination thereof.

As used herein, the term “silicon-containing film” refers to a film comprising at least one of silicon, silicon oxynitride, silicon oxide, silicon dioxide, silicon carbide, silicon carbonitride, silicon oxycarbonitride, carbon-doped silicon nitride, carbon-doped silicon oxide, carbon-doped silicon oxynitride, or any combination thereof. The term does not refer to silicon nitride films. For example, the silicon-containing film may comprise at least one of a SiO film, a SiN film, a SiOC film, a SiCN film, a SiOCN film, or any combination thereof. In some embodiments, the silicon-containing film has a thickness of 20 Å to 2000 Å, or any range or subrange between 20 Å to 2000 Å. In some embodiments, the silicon-containing film does not comprise a nitride.

Some embodiments relate to precursors and related methods. At least some of these embodiments relate to cyclosilazane compounds useful as precursors in the fabrication of microelectronic devices, including semiconductor devices, and the like. For example, the cyclosilazane compounds can be used to form silicon-containing films by one or more deposition processes. Examples of deposition processes include, without limitation, at least one of a chemical vapor deposition (CVD) process, a digital or pulsed chemical vapor deposition process, a plasma-enhanced cyclical chemical vapor deposition process (PECCVD), a flowable chemical vapor deposition process (FCVD), an atomic layer deposition (ALD) process, a thermal atomic layer deposition, a plasma-enhanced atomic layer deposition (PEALD) process, a metal organic chemical vapor deposition (MOCVD) process, a plasma-enhanced chemical vapor deposition (PECVD) process, or any combination thereof. In some embodiments, the deposition process does not comprise any chemical vapor deposition process.

Some embodiments relate to a precursor. In some embodiments, the precursor comprises a compound of the formula:

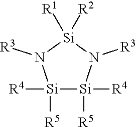

where:
R¹, R², R³, R⁴, and R⁵ are each independently a hydrogen, an alkyl, or a cycloalkyl, provided that R⁴ and R⁵ are not both hydrogen.

In some embodiments, the precursor (or the compound of the formula above) is a reaction product of:

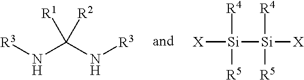

where:
R¹, R², R³, R⁴, and R⁵ are each independently a hydrogen, an alkyl, or a cycloalkyl, provided that R⁴ and R⁵ are not both hydrogen; and
X is Cl, Br, I, or F.

In some embodiments, R¹ is an alkyl and R² is one of a hydrogen or an alkyl. In some embodiments, R¹ is an alkyl and R² is one of a hydrogen or a cycloalkyl. In some embodiments, R¹ is an alkyl and R² is one of an alkyl or a cycloalkyl. In some embodiments, R¹ is a cycloalkyl and R² is one of a hydrogen or an alkyl. In some embodiments, R¹ is a cycloalkyl and R² is one of a hydrogen or a cycloalkyl. In some embodiments, R¹ is a cycloalkyl and R² is one of an alkyl or a cycloalkyl. In some embodiments, R¹ is a hydrogen and R² is one of a hydrogen or an alkyl. In some embodiments, R¹ is a hydrogen and R² is one of a hydrogen or a cycloalkyl. In some embodiments, R¹ is a hydrogen and R² is one of an alkyl or a cycloalkyl. In some embodiments, R¹ is an alkyl and R² is a hydrogen. In some embodiments, R¹ is an alkyl and R² is an alkyl. In some embodiments, the alkyl of R¹ and R² is the same. In some embodiments, the alkyl of R¹ and R² is different. In some embodiments, the cycloalkyl of R¹ and R² is the same. In some embodiments, the cycloalkyl of R¹ and R² is different.

In some embodiments, R³ is a hydrogen, an alkyl, or a cycloalkyl. In some embodiments, R³ is a hydrogen or an alkyl. In some embodiments, R³ is a hydrogen or a cycloalkyl. In some embodiments, R³ is an alkyl or a cycloalkyl. In some embodiments, R³ is an alkyl. In some embodiments, R³ is a cycloalkyl. In some embodiments, R³ is a hydrogen.

In some embodiments, R⁴ is an alkyl and R⁵ is one of a hydrogen or an alkyl. In some embodiments, R⁴ is an alkyl and R⁵ is one of a hydrogen or a cycloalkyl. In some embodiments, R⁴ is an alkyl and R⁵ is one of an alkyl or a cycloalkyl. In some embodiments, R⁴ is a cycloalkyl and R⁵ is one of a hydrogen or an alkyl. In some embodiments, R⁴ is a cycloalkyl and R⁵ is one of a hydrogen or a cycloalkyl. In some embodiments, R⁴ is a cycloalkyl and R⁵ is one of an alkyl or a cycloalkyl. In some embodiments, R⁴ is a hydrogen and R⁵ is one of an alkyl or a cycloalkyl. In some embodiments, R⁴ is an alkyl and R⁵ is a hydrogen. In some embodiments, R⁴ is an alkyl and R⁵ is an alkyl. In some embodiments, the alkyl of R⁴ and R⁵ is the same. In some embodiments, the alkyl of R⁴ and R⁵ is different. In some embodiments, the cycloalkyl of R⁴ and R⁵ is the same. In some embodiments, the cycloalkyl of R⁴ and R⁵ is different.

Non-limiting examples of the precursor include at least one of the following:

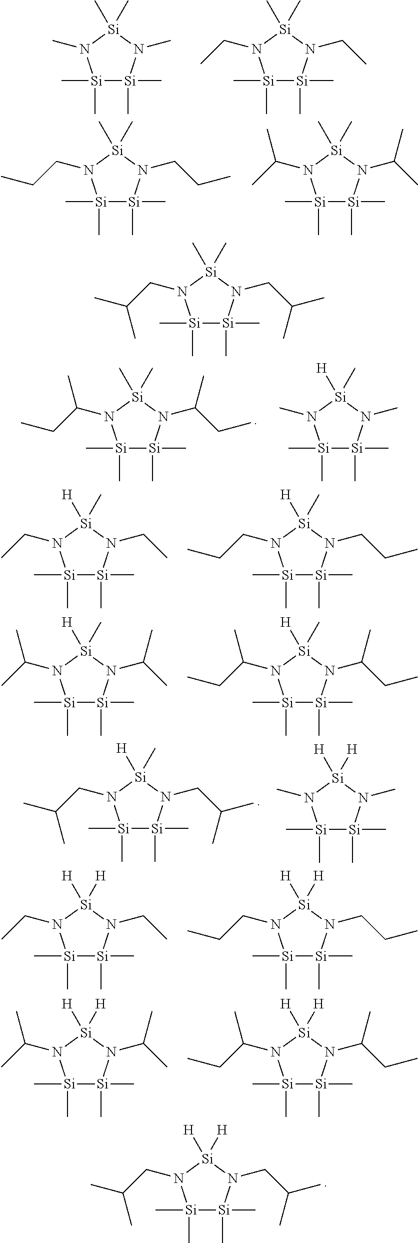

In some embodiments, the precursor has a purity of 96% or greater. In some embodiments, for example, the precursor has a purity of at least 96%, 97%, 98%, 99%, 99.9%, 99.99%, 99.999%, 99.9999%, 99.99999%, or greater. In some embodiments, the precursor has a purity of 96% to 99.99999%, or any range or subrange between 96% and 99.99999%. In some embodiments, for example, the precursor has a purity of 97% to 99.99999%, 98% to 99.99999%, 99% to 99.99999%, 97% to 99.9999%, 97% to 99.999%, 97% to 99.99%, or 97% to 99.9%. In some embodiments, the purity is measured using ¹H NMR spectroscopy.

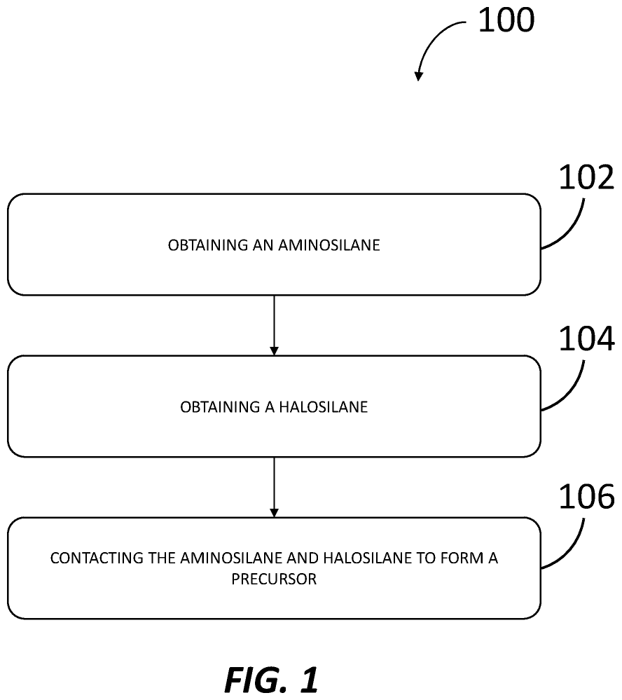

FIG. 1 is a flowchart of a method 100 for forming a precursor, according to some embodiments. As shown in FIG. 1, in some embodiments, the method 100 comprises one or more of the following steps: obtaining 102 an aminosilane, obtaining 104 a halosilane, and contacting 106 the aminosilane and the halosilane to form a precursor.

At step 102, in some embodiments, the method 100 comprises obtaining an aminosilane. In some embodiments, the aminosilane is a compound of the formula:

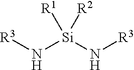

where:
R¹, R², and R³ are each independently a hydrogen, an alkyl, or a cycloalkyl.

In some embodiments, R¹ is an alkyl and R² is one of a hydrogen or an alkyl. In some embodiments, R¹ is an alkyl and R² is one of a hydrogen or a cycloalkyl. In some embodiments, R¹ is an alkyl and R² is one of an alkyl or a cycloalkyl. In some embodiments, R¹ is a cycloalkyl and R² is one of a hydrogen or an alkyl. In some embodiments, R¹ is a cycloalkyl and R² is one of a hydrogen or a cycloalkyl. In some embodiments, R¹ is a cycloalkyl and R² is one of an alkyl or a cycloalkyl. In some embodiments, R¹ is a hydrogen and R² is one of a hydrogen or an alkyl. In some embodiments, R¹ is a hydrogen and R² is one of a hydrogen or a cycloalkyl. In some embodiments, R¹ is a hydrogen and R² is one of an alkyl or a cycloalkyl. In some embodiments, R¹ is an alkyl and R² is a hydrogen. In some embodiments, R¹ is an alkyl and R² is an alkyl. In some embodiments, the alkyl of R¹ and R² is the same. In some embodiments, the alkyl of R¹ and R² is different. In some embodiments, the cycloalkyl of R¹ and R² is the same. In some embodiments, the cycloalkyl of R¹ and R² is different.

In some embodiments, R³ is a hydrogen, an alkyl, or a cycloalkyl. In some embodiments, R³ is a hydrogen or an alkyl. In some embodiments, R³ is a hydrogen or a cycloalkyl. In some embodiments, R³ is an alkyl or a cycloalkyl. In some embodiments, R³ is an alkyl. In some embodiments, R³ is a cycloalkyl. In some embodiments, R³ is a hydrogen.

At step 104, in some embodiments, the method 100 comprises obtaining an halosilane. In some embodiments, the halosilane is a compound of the formula:

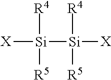

where:
X is Cl, Br, I, or F;
R⁴ and R⁵ are each independently a hydrogen, an alkyl, or a cycloalkyl, provided that R⁴ and R⁵ are not both hydrogen.

In some embodiments, R⁴ is an alkyl and R⁵ is one of a hydrogen or an alkyl. In some embodiments, R⁴ is an alkyl and R⁵ is one of a hydrogen or a cycloalkyl. In some embodiments, R⁴ is an alkyl and R⁵ is one of an alkyl or a cycloalkyl. In some embodiments, R⁴ is a cycloalkyl and R⁵ is one of a hydrogen or an alkyl. In some embodiments, R⁴ is a cycloalkyl and R⁵ is one of a hydrogen or a cycloalkyl. In some embodiments, R⁴ is a cycloalkyl and R⁵ is one of an alkyl or a cycloalkyl. In some embodiments, R⁴ is a hydrogen and R⁵ is one of an alkyl or a cycloalkyl. In some embodiments, R⁴ is an alkyl and R⁵ is a hydrogen. In some embodiments, R⁴ is an alkyl and R⁵ is an alkyl. In some embodiments, the alkyl of R⁴ and R⁵ is the same. In some embodiments, the alkyl of R⁴ and R⁵ is different. In some embodiments, the cycloalkyl of R⁴ and R⁵ is the same. In some embodiments, the cycloalkyl of R⁴ and R⁵ is different.

At step 106, in some embodiments, the method 100 comprises contacting the aminosilane and the halosilane to form a precursor. In some embodiments, the precursor is a compound of the formula:

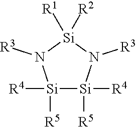

where:
R¹, R², R³, R⁴, and R⁵ are as defined above.

The contacting may proceed in a presence of at least one of an activator, a solvent, or any combination thereof. In some embodiments, for example, the contacting proceeds in the presence of an alkyllithium. For example, in some embodiments, the contacting proceeds in the presence of n-butyllithium. In some embodiments, the solvent comprises at least one of hexane, octane, toluene, diethyl ether, tetrahydrofuran (THF), or any combination thereof.

The contacting may proceed at or to a temperature of −35° C. to 10° C., or any range or subrange between −35° C. and 10° C. For example, in some embodiments, the contacting proceeds at or to a temperature of −35° C. to 5° C., −35° C. to 0° C., −35° ° C. to −5° C., −35° C. to −10° C., −35° C. to −15° C., −35° C. to −20° C., −35° C. to −25° C., −35° ° C. to −30° C., −30° ° C. to 10° ° C., −25° C. to 10° C., −20° C. to 10° ° C., −10° C. to 10° C., −5° ° C. to 10° C., 0° C. to 10° C., or 5° C. to 10° C.

Non-limiting examples of the precursor include at least one of the following:

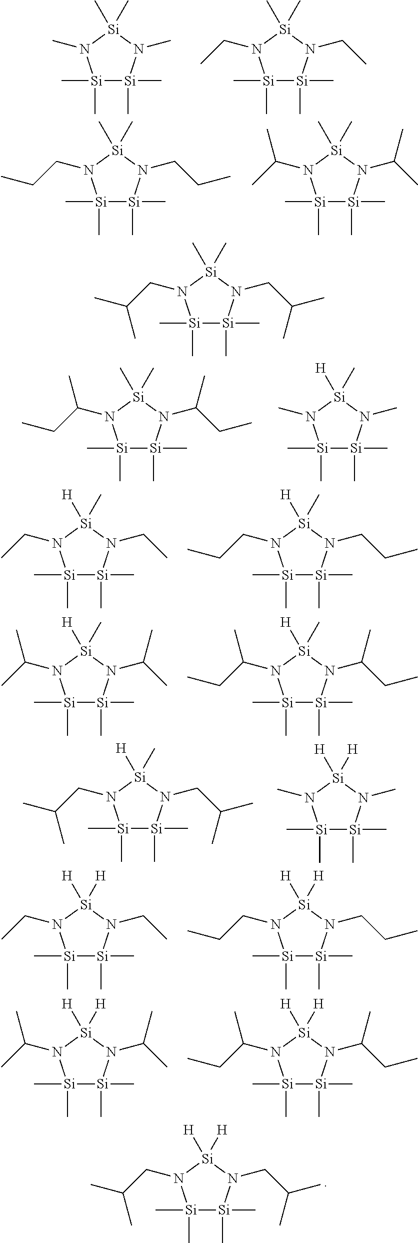

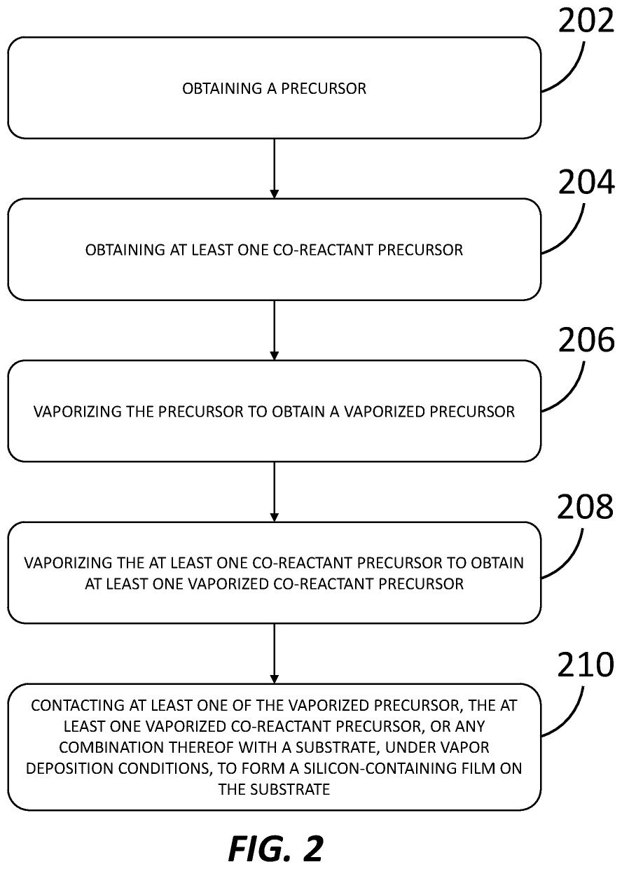

FIG. 2 is a flowchart of a method for making a silicon-containing film 200, according to some embodiments. As shown in FIG. 2, the method for making a silicon-containing film 200 may comprise one or more of the following steps: obtaining 202 a precursor, obtaining 204 at least one co-reactant precursor, vaporizing 206 the precursor to obtain a vaporized precursor, vaporizing 208 the at least one co-reactant precursor to obtain at least one vaporized co-reactant precursor, contacting 210 at least one of the vaporized precursor, the at least one vaporized co-reactant precursor, or any combination thereof with a substrate, under vapor deposition conditions, to form a silicon-containing film on the substrate.

The step 202 may comprise obtaining a precursor. The precursor may comprise any one or more of the precursors disclosed herein. The obtaining may comprise obtaining a container or other vessel comprising the precursor. In some embodiments, the precursor may be obtained in a container or other vessel in which the precursor is to be vaporized.

The step 204 may comprise obtaining at least one co-reactant precursor. In some embodiments, the at least one co-reactant precursor comprises at least one of an oxidizing gas, a reducing gas, a hydrocarbon, or any combination thereof. The at least one co-reactant precursor may be selected to obtain a desired silicon-containing film. In some embodiments, the at least one co-reactant precursor may comprise at least one of N₂, H₂, NH₃, N₂H₄, CH₃HNNH₂, CH₃HNNHCH₃, NCH₃H₂, NCH₃CH₂H₂, N(CH₃)₂H, N(CH₃CH₂)₂H, N(CH₃)₃, N(CH₃CH₂)₃, Si(CH₃)₂NH, pyrazoline, pyridine, ethylene diamine, a radical thereof, or any combination thereof. In some embodiments, the at least one co-reactant precursor may comprise at least one of H₂, O₂, O₃, H₂O, H₂O₂, NO, N₂O, NO₂, CO, CO₂, a carboxylic acid, an alcohol, a diol, a radical thereof, or any combination thereof. In some embodiments, the at least one co-reactant precursor comprises at least one of methane, ethane, ethylene, acetylene, or any combination thereof. The obtaining may comprise obtaining a container or other vessel comprising the at least one co-reactant precursor. In some embodiments, the at least one co-reactant precursor may be obtained in a container or other vessel in which the at least one co-reactant precursor is to be vaporized. In some embodiments, the method further comprises an inert gas, such as, for example, at least one of argon, helium, nitrogen, or any combination thereof.

The step 206 may comprise vaporizing the precursor to obtain a vaporized precursor. The vaporizing may comprise heating the precursor sufficient to obtain the vaporized precursor. In some embodiments, the vaporizing may comprise heating a container comprising the precursor. In some embodiments, the vaporizing may comprise heating the precursor in a deposition chamber in which the vapor deposition process is performed. In some embodiments, the vaporizing may comprise heating a conduit for delivering the precursor, vaporized precursor, or any combination thereof to, for example, a deposition chamber. In some embodiments, the vaporizing may comprise operating a vapor delivery system comprising the precursor. In some embodiments, the vaporizing may comprise heating to a temperature sufficient to vaporize the precursor to obtain the vaporized precursor. In some embodiments, the vaporizing may comprise heating to a temperature below a decomposition temperature of at least one of the precursor, the vaporized precursor, or any combination thereof. In some embodiments, the precursor may be present in a gas phase, in which case the step 206 is optional and not required. For example, the precursor may comprise the vaporized precursor.

The step 208 may comprise vaporizing the at least one co-reactant precursor to obtain the at least one vaporized co-reactant precursor. In some embodiments, the vaporizing may comprise heating the at least one co-reactant precursor sufficient to obtain the at least one vaporized co-reactant precursor. In some embodiments, the vaporizing may comprise heating a container comprising the at least one co-reactant precursor. In some embodiments, the vaporizing may comprise heating the at least one co-reactant precursor in a deposition chamber in which the vapor deposition process is performed. In some embodiments, the vaporizing may comprise heating a conduit for delivering the at least one co-reactant precursor, the at least one vaporized co-reactant precursor, or any combination thereof to, for example, a deposition chamber. In some embodiments, the vaporizing may comprise operating a vapor delivery system comprising the at least one co-reactant precursor. In some embodiments, the vaporizing may comprise heating to a temperature sufficient to vaporize the at least one co-reactant precursor to obtain the at least one vaporized co-reactant precursor. In some embodiments, the vaporizing may comprise heating to a temperature below a decomposition temperature of at least one of the at least one co-reactant precursor, the at least one vaporized co-reactant precursor, or any combination thereof. In some embodiments, the at least one co-reactant precursor may be present in a gas phase, in which case the step 208 is optional and not required. For example, the at least one co-reactant precursor may comprise the at least one vaporized co-reactant precursor.

The step 210 may comprise contacting at least one of the vaporized precursor, the at least one vaporized co-reactant precursor, or any combination thereof, with the substrate, under vapor deposition conditions, sufficient to form a silicon-containing film on a surface of the substrate. The contacting may be performed in any system, apparatus, device, assembly, chamber thereof, or component thereof suitable for vapor deposition processes, including, for example and without limitation, a deposition chamber, among others. The vaporized precursor and the at least one co-reactant precursor may be contacted with the substrate at the same time. For example, each of the vaporized precursor, the at least one vaporized co-reactant precursor, and the substrate may be present in the deposition chamber at the same time. That is, in some embodiments, the contacting may comprise contemporaneous contacting or simultaneous contacting of the vaporized precursor and the at least one vaporized co-reactant precursor with the substrate. In some embodiments, the contacting may comprise contacting the vaporized precursor and the at least one vaporized co-reactant precursor with the substrate at different times (e.g., sequential contacting or contacting each precursor with the substrate in the absence of the other precursor).

The vapor deposition conditions may comprise conditions for vapor deposition processes. Examples of vapor deposition conditions include, without limitation, vapor deposition conditions for vapor deposition processes including at least one of a chemical vapor deposition (CVD) process, a digital or pulsed chemical vapor deposition process, a plasma-enhanced cyclical chemical vapor deposition process (PECCVD), a flowable chemical vapor deposition process (FCVD), an atomic layer deposition (ALD) process, a thermal atomic layer deposition process, a plasma-enhanced atomic layer deposition (PEALD) process, a metal organic chemical vapor deposition (MOCVD) process, a plasma-enhanced chemical vapor deposition (PECVD) process, or any combination thereof. In some embodiments, the vapor deposition conditions do not comprise conditions for any chemical vapor deposition processes.

The vapor deposition conditions may comprise a deposition temperature. The deposition temperature may be a temperature less than the thermal decomposition temperature of at least one of the vaporized precursor, the at least one vaporized co-reactant precursor, or any combination thereof. The deposition temperature may be sufficiently high to reduce or avoid condensation of at least one of the vaporized precursor, the at least one vaporized co-reactant precursor, or any combination thereof. In some embodiments, the substrate may be heated to the deposition temperature. In some embodiments, the chamber or other vessel in which the substrate is contacted with the vaporized precursor and the at least one vaporized co-reactant precursor is heated to the deposition temperature. In some embodiments, at least one of the vaporized precursor, the at least one vaporized co-reactant precursor, or any combination thereof may be heated to the deposition temperature.

The deposition temperature may be a temperature of 200° ° C. to 2500° C. In some embodiments, the deposition temperature may be a temperature of 500° C. to 700° C. For example, in some embodiments, the deposition temperature may be a temperature of 500° C. to 680° C., 500° C. to 660° C., 500° C. to 640° ° C., 500° C. to 620° C., 500° ° C. to 600° C., 500° C. to 580° C., 500° C. to 560° C., 500° C. to 540° C., 500° C. to 520° C., 520° ° C. to 700° C., 540° C. to 700° C., 560° C. to 700° C., 580° C. to 700° C., 600° ° C. to 700° C., 620° C. to 700° C., 640° ° C. to 700° C., 660° C. to 700° C., or 680° ° C. to 700° C. In other embodiments, the deposition temperature may be a temperature of greater than 200° C. to 2500° C., such as, for example and without limitation, a temperature of 400° C. to 2000, 500° C. to 2000° ° C., 550° C. to 2400° C., 600° C. to 2400° C., 625° ° C. to 2400° C., 650° C. to 2400° C., 675° C. to 2400° ° C., 700° C. to 2400° C., 725° C. to 2400° C., 750° ° C. to 2400° C., 775° C. to 2400° C., 800° C. to 2400° C., 825° C. to 2400° C., 850° C. to 2400° C., 875° C. to 2400° C., 900° C. to 2400° C., 925° C. to 2400° C., 950° C. to 2400° C., 975° C. to 2400° C., 1000° C. to 2400° C., 1025° C. to 2400° C., 1050° C. to 2400° C., 1075° C. to 2400° C., 1100° ° C. to 2400° C., 1200° ° C. to 2400° C., 1300° C. to 2400° C., 1400° ° C. to 2400° C., 1500° C. to 2400° C., 1600° C. to 2400° C., 1700° C. to 2400° C., 1800° C. to 2400° C., 1900° C. to 2400° C., 2000° C. to 2400° C., 2100° C. to 2400° C., 2200° ° C. to 2400° C., 2300° C. to 2400° C., 500° C. to 2000° C., 500° C. to 1900° C., 500° C. to 1800° C., 500° C. to 1700° C., 500° C. to 1600° C., 500° ° C. to 1500° C., 500° C. to 1400° C., 500° C. to 1300° C., 500° ° C. to 1200° ° C., 500° C. to 1100° C., 500° C. to 1000° C., 500° ° C. to 1000° C., 500° C. to 900° C., or 500° C. to 800° C.

The vapor deposition conditions may comprise a deposition pressure. In some embodiments, the deposition pressure may comprise a vapor pressure of at least one of the vaporized precursor, the at least one vaporized co-reactant precursor, or any combination thereof. In some embodiments, the deposition pressure may comprise a chamber pressure.

The deposition pressure may be a pressure of 0.001 Torr to 100 Torr. For example, in some embodiments, the deposition pressure may be a pressure of 1 Torr to 30 Torr, 1 Torr to 25 Torr, 1 Torr to 20 Torr, 1 Torr to 15 Torr, 1 Torr to 10 Torr, 5 Torr to 50 Torr, 5 Torr to 40 Torr, 5 Torr to 30 Torr, 5 Torr to 20 Torr, or 5 Torr to 15 Torr. In other embodiments, the deposition pressure may be a pressure of 1 Torr to 100 Torr, 5 Torr to 100 Torr, 10 Torr to 100 Torr, 15 Torr to 100 Torr, 20 Torr to 100 Torr, 25 Torr to 100 Torr, 30 Torr to 100 Torr, 35 Torr to 100 Torr, 40 Torr to 100 Torr, 45 Torr to 100 Torr, 50 Torr to 100 Torr, 55 Torr to 100 Torr, 60 Torr to 100 Torr, 65 Torr to 100 Torr, 70 Torr to 100 Torr, 75 Torr to 100 Torr, 80 Torr to 100 Torr, 85 Torr to 100 Torr, 90 Torr to 100 Torr, 95 Torr to 100 Torr, 1 Torr to 95 Torr, 1 Torr to 90 Torr, 1 Torr to 85 Torr, 1 Torr to 80 Torr, 1 Torr to 75 Torr, or 1 Torr to 70 Torr. In other further embodiments, the deposition pressure may be a pressure of 1 mTorr to 100 mTorr, 1 mTorr to 90 mTorr, 1 mTorr to 80 mTorr, 1 mTorr to 70 mTorr, 1 mTorr to 60 mTorr, 1 mTorr to 50 mTorr, 1 mTorr to 40 mTorr, 1 mTorr to 30 mTorr, 1 mTorr to 20 mTorr, 1 mTorr to 10 mTorr, 100 mTorr to 300 mTorr, 150 mTorr to 300 mTorr, 200 mTorr to 300 mTorr, or 150 mTorr to 250 mTorr, or 150 mTorr to 225 mTorr.

The substrate may comprise at least one of Si, Co, Cu, AI, W, WN, WC, TIN, Mo, MOC, SiO₂, W, SiN, WCN, Al₂O₃, AlN, ZrO₂, La₂O₃, TaN, RuO₂, IrO₂, Nb₂O₃, Y₂O₃, hafnium oxide, or any combination thereof. In some embodiments, the silicon-containing film may comprise at least one of at least one of silicon, silicon nitride, silicon oxynitride, silicon oxide, silicon dioxide, silicon carbide, silicon carbonitride, silicon oxycarbonitride, carbon-doped silicon nitride, carbon-doped silicon oxide, carbon-doped silicon oxynitride, or any combination thereof. In some embodiments, the substrate may comprise other silicon-based substrates, such as, for example, one or more of polysilicon substrates, metallic substrates, and dielectric substrates.

Some embodiments relate to a silicon-containing film on a surface of a substrate. In some embodiments, the silicon-containing film comprises any film formed according to the methods disclosed herein. In some embodiments, the silicon-containing film comprises any film prepared from the precursors disclosed herein.

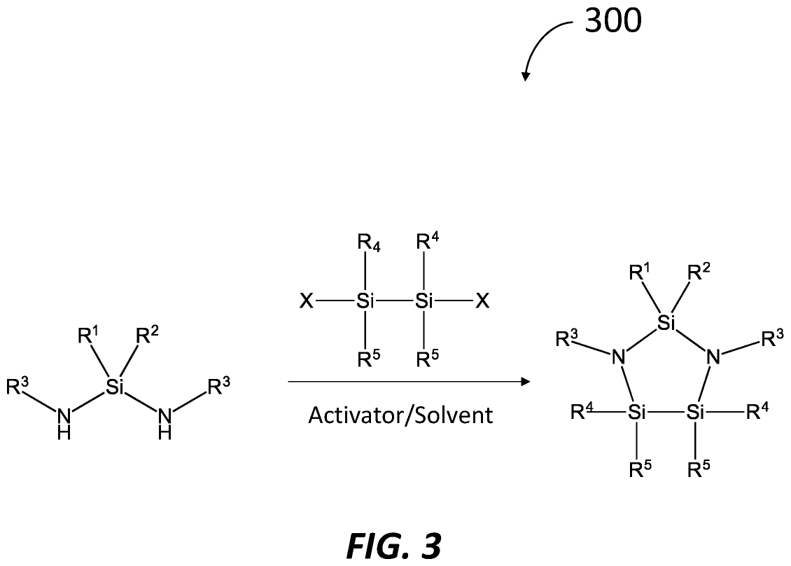

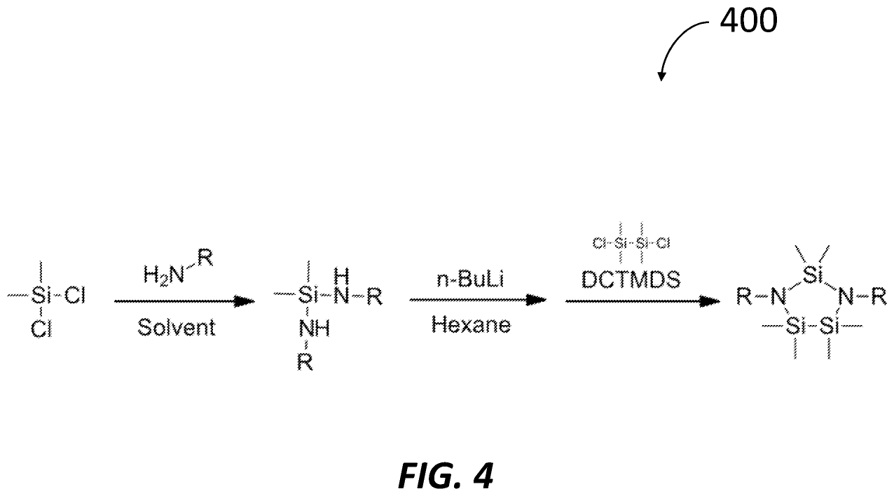

Reaction schemes for forming the precursor are presented in FIGS. 3-4. FIG. 3 depicts a reaction scheme for forming a precursor, according to some embodiments. FIG. 4 depicts a reaction scheme for forming a precursor, according to some embodiments.

### Example 1

### Synthesis of 2,2,4,4,5,5-Hexamethyl-1,3-dipropyl-1,3,2,4,5-diazatrisilolidine

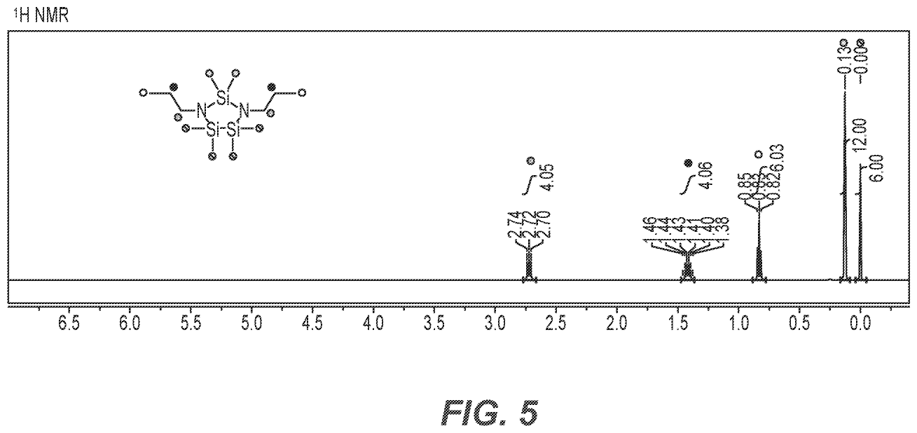

To a solution of bis(n-propylamino)dimethylsilane (5 g, 0.028 mol) in hexane at −20° C., n-butyllithium (2.5 M in hexane, 23 ml, 0.057 mol) was added dropwise. The solution was allowed to be at room temperature for 2 h before 1,2-dichlorotetramethyldisilane (5.3 g, 0.028 mol) was added dropwise at 0° C. After stirring overnight at room temperature, a white solid was filtered. Volatiles were removed under vacuum and the crude product was purified by distillation (70° C. at 0.7 torr) to obtain the 2,2,4,4,5,5-Hexamethyl-1,3-dipropyl-1,3,2,4,5-diazatrisilolidine product as a colorless liquid. Yield 6.4 g (75%); purity 98%. FIG. 5 is a ¹H NMR spectrum of the 2,2,4,4,5,5-Hexamethyl-1,3-dipropyl-1,3,2,4,5-diazatrisilolidine product, according to some embodiments.

### Example 2

### Synthesis of 2,2,4,4,5,5-Hexamethyl-1,3-diisopropyl-1,3,2,4,5-diazatrisilolidine

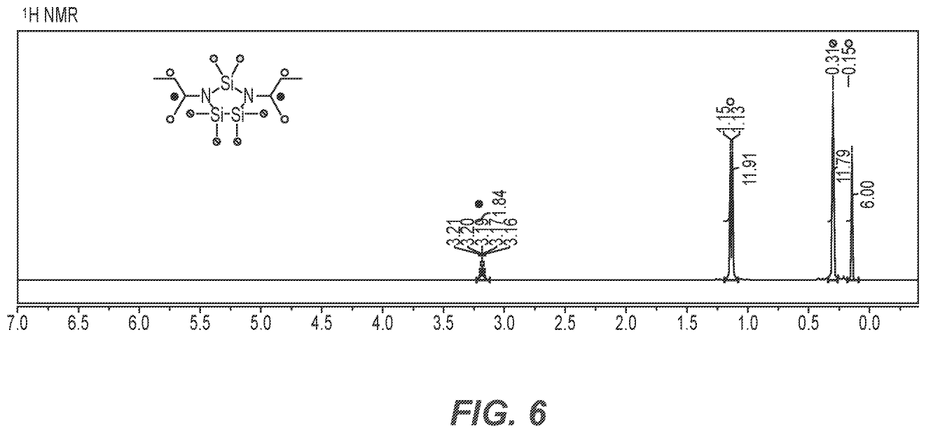

To a solution of bis(iso-propylamino)dimethylsilane (5 g, 0.028 mol) in hexane at −20° C., n-butyllithium (2.5 M in hexane, 23 ml, 0.057 mol) was added dropwise. The solution was allowed to be at room temperature for 2 h before 1,2-dichlorotetramethyldisilane (5.3 g, 0.028 mol) was added dropwise at 0° C. After stirring overnight at room temperature, a white solid was filtered. Volatiles were removed under vacuum and the crude product was purified by sublimation (40° C. at 0.5 torr) to obtain the 2,2,4,4,5,5-Hexamethyl-1,3-diisopropyl-1,3,2,4,5-diazatrisilolidine product as a colorless crystal. Yield 5.2 g (62%); purity 98%. FIG. 6 is a ¹H NMR spectrum of the 2,2,4,4,5,5-Hexamethyl-1,3-diisopropyl-1,3,2,4,5-diazatrisilolidine product, according to some embodiments.

### Aspects

Various Aspects are described below. It is to be understood that any one or more of the features recited in the following Aspect(s) can be combined with any one or more other Aspect(s).

Aspect 1. A precursor comprising:
a compound of the formula:

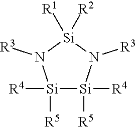

where:
   R¹, R², R³, R⁴, and R⁵ are each independently a hydrogen, a linear alkyl, a branched alkyl, or a cycloalkyl, provided that R⁴ and R⁵ are not both hydrogen;
wherein the compound is a reaction product of:

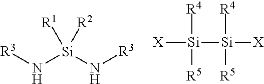

where:
   R¹, R², R³, R⁴, and R⁵ are as defined above;
   X is Cl, Br, I, or F.

Aspect 2. The composition according to Aspect 1, wherein R¹ is methyl and R² is hydrogen.

Aspect 3. The composition according to Aspect 1, wherein R¹ is methyl and R² is methyl.

Aspect 4. The composition according to any one of Aspects 1-3, wherein R⁴ and R⁵ are methyl

Aspect 5. The composition according to any one of Aspects 1-4, wherein R³ is a linear C₁-C₆ alkyl.

Aspect 6. The composition according to any one of Aspects 1-5, wherein R³ is a branched C₃-C₆ alkyl.

Aspect 7. The composition according to any one of Aspects 1-5, wherein R³ is a C₃-C₆ cycloalkyl.

Aspect 8. The composition according to any one of Aspects 1-7, wherein the compound is at least one of the following:

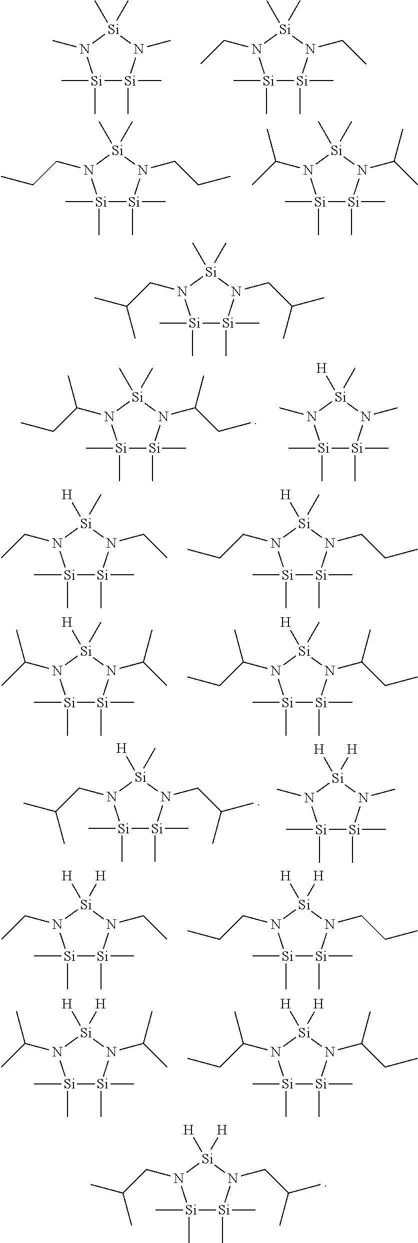

Aspect 9. A method comprising:
obtaining an aminosilane,
   wherein the aminosilane is a compound of the formula:

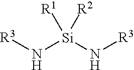

where:
   R¹, R², and R³ are each independently a hydrogen, a linear alkyl, a branched alkyl, or a cycloalkyl;
obtaining a halosilane,
   wherein the halosilane is a compound of the formula:

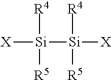

where:
   X is Cl, Br, I, or F;
   R⁴ and R⁵ are each independently a hydrogen, a linear alkyl, a branched alkyl, or a cycloalkyl, provided that R⁴ and R⁵ are not both hydrogen;
contacting the aminosilane and the halosilane to form a precursor of the formula:

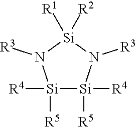

where:
   R¹, R², R³, R⁴, and R⁵ are as defined above.

Aspect 10. The method according to Aspect 9, wherein R¹ is methyl and R² is hydrogen.

Aspect 11. The method according to Aspect 9, wherein R¹ is ethyl and R² is methyl.

Aspect 12. The method according to any one of Aspects 9-11, wherein R⁴ and R⁵ are methyl

Aspect 13. The method according to any one of Aspects 9-12, wherein R³ is a linear C₁-C₆ alkyl, a branched C₃-C₆ alkyl, or a C₃-C₆ cycloalkyl.

Aspect 14. The method according to any one of Aspects 9-13, wherein the precursor comprises at least one of the following:

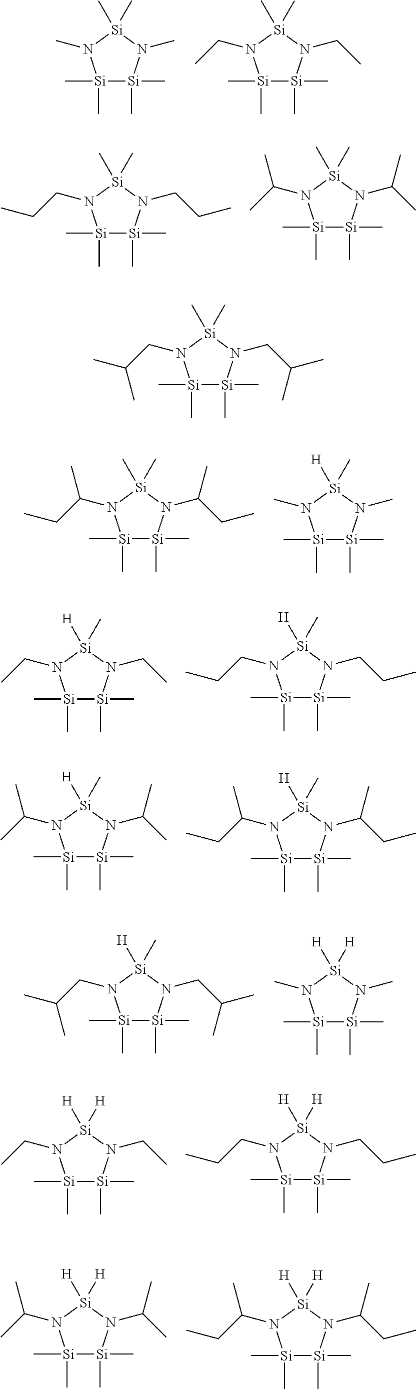

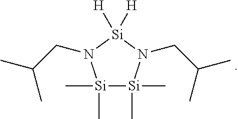 [SMILES: CC(C)CN1[SiH2]N(CC(C)C)[Si](C)(C)[Si]1(C)C]

Aspect 15. A method comprising:
obtaining a precursor;
   wherein the precursor comprises a compound of the formula:

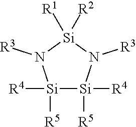

where:
   R¹, R², R³, R⁴, and R⁵ are each independently a hydrogen, a linear alkyl, a branched alkyl, or a cycloalkyl, provided that R⁴ and R⁵ are not both hydrogen;

obtaining at least one co-reactant precursor;

vaporizing the precursor to obtain a vaporized precursor;

vaporizing the at least one co-reactant precursor to obtain at least one vaporized co-reactant precursor;
contacting at least one of the vaporized precursor, the at least one vaporized co-reactant precursor, or any combination thereof, with a substrate, under vapor deposition conditions, to form a silicon-containing film on the substrate.

Aspect 16. The method according to Aspect 15, wherein R¹ is methyl and R² is hydrogen.

Aspect 17. The method according to Aspect 15, wherein R¹ is methyl and R² is methyl.

Aspect 18. The method according to any one of Aspects 15-17, wherein R⁴ and R⁵ are methyl

Aspect 19. The method according to any one of Aspects 15-18, wherein R³ is a linear C₁-C₆ alkyl, a branched C₃-C₆ alkyl, or a C₃-C₆ cycloalkyl.

Aspect 20. The method according to any one of Aspects 15-19, wherein the precursor comprises at least one of the following:

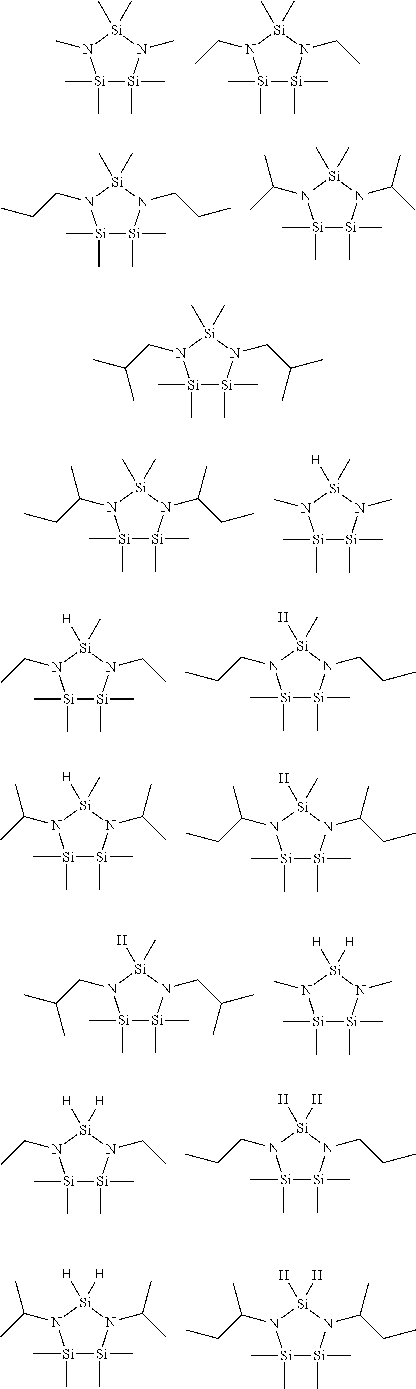

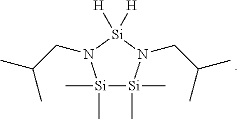 [SMILES: CC(C)CN1[SiH2]N(CC(C)C)[Si](C)(C)[Si]1(C)C]

It is to be understood that changes may be made in detail, especially in matters of the construction materials employed and the shape, size, and arrangement of parts without departing from the scope of the present disclosure. This Specification and the embodiments described are examples, with the true scope and spirit of the disclosure being indicated by the claims that follow.

What is claimed is:

1. A precursor comprising:
a compound of the formula: 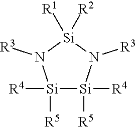
where:
R¹, R², R³, R⁴, and R⁵ are each independently a hydrogen, a linear alkyl, a branched alkyl, or a cycloalkyl, provided that R⁴ and R⁶ are not both hydrogen;
wherein the compound is a reaction product of: 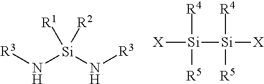
where:
R¹, R², R³, R⁴, and R⁵ are as defined above;
X is Cl, Br, I, or F.

2. The composition of claim 1, wherein R¹ is methyl and R² is hydrogen.

3. The composition of claim 1, wherein R¹ is methyl and R² is methyl.

4. The composition of claim 1, wherein R⁴ and R⁵ are methyl

5. The composition of claim 1, wherein R³ is a linear C₁-C₆ alkyl.

6. The composition of claim 1, wherein R³ is a branched C₃-C₆ alkyl.

7. The composition of claim 1, wherein R³ is a C₃-C₆ cycloalkyl.

8. The composition of claim 1, wherein the precursor has a purity of at least 96%.

9. The composition of claim 1, wherein the compound is at least one of the following:

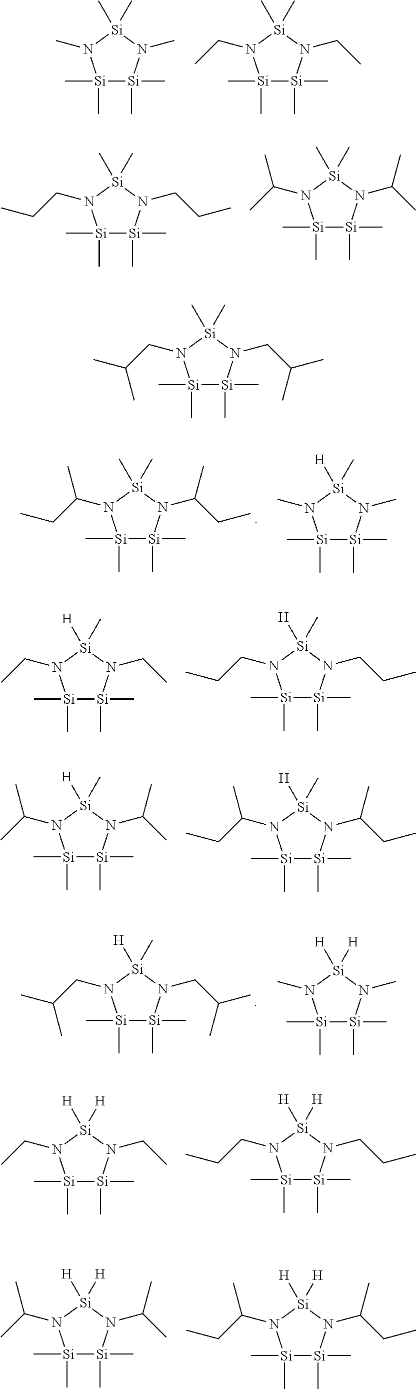

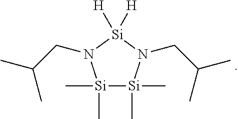 [SMILES: CC(C)CN1[SiH2]N(CC(C)C)[Si](C)(C)[Si]1(C)C]

10. A method comprising:
obtaining an aminosilane,
wherein the aminosilane is a compound of the formula: 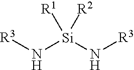
where:
R¹, R², and R³ are each independently a hydrogen, a linear alkyl, a branched alkyl, or a cycloalkyl;
obtaining a halosilane,
wherein the halosilane is a compound of the formula: 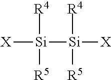
where:
X is Cl, Br, I, or F;
R⁴ and R⁵ are each independently a hydrogen, a linear alkyl, a branched alkyl, or a cycloalkyl, provided that R⁴ and R⁵ are not both hydrogen;
contacting the aminosilane and the halosilane to form a precursor of the formula: 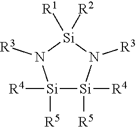
where:
R¹, R², R³, R⁴, and R⁵ are as defined above.

11. The method of claim 10, wherein R¹ is methyl and R² is hydrogen.

12. The method of claim 10, wherein R¹ is methyl and R² is methyl.

13. The method of claim 10, wherein R⁴ and R⁵ are methyl

14. The method of claim 10, wherein R³ is a linear C₁-C₆ alkyl, a branched C₃-C₆ alkyl, or a C₃-C₆ cycloalkyl.

15. The method of claim 10, wherein the precursor is at least one of the following:

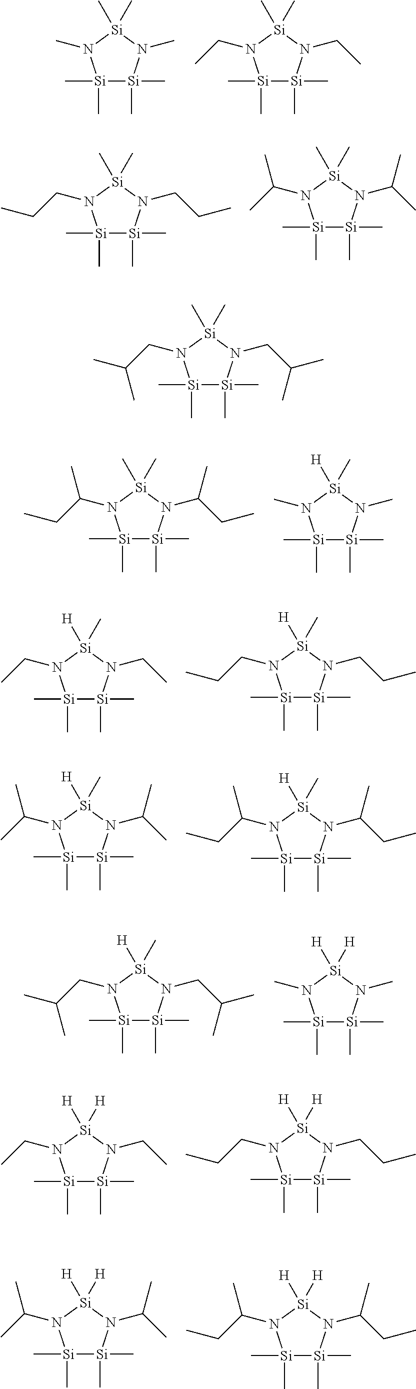

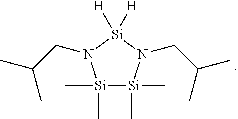 [SMILES: CC(C)CN1[SiH2]N(CC(C)C)[Si](C)(C)[Si]1(C)C]

16. A method comprising:
obtaining a precursor;
wherein the precursor comprises a compound of the formula: 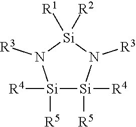
where:
R¹, R², R³, R⁴, and R⁵ are each independently a hydrogen, a linear alkyl, a branched alkyl, or a cycloalkyl, provided that R⁴ and R⁵ are not both hydrogen;
obtaining at least one co-reactant precursor;
vaporizing the precursor to obtain a vaporized precursor;
vaporizing the at least one co-reactant precursor to obtain at least one vaporized co-reactant precursor;
contacting at least one of the vaporized precursor, the at least one vaporized co-reactant precursor, or any combination thereof, with a substrate, under vapor deposition conditions, to form a silicon-containing film on the substrate.

17. The method of claim 16, wherein the vapor deposition conditions include atomic layer deposition conditions or chemical vapor deposition conditions.

18. The method of claim 16, wherein R⁴ and R⁵ are methyl

19. The method of claim 16, wherein R³ is a linear C₁-C₆ alkyl, a branched C₃-C₆ alkyl, or a C₃-C₆ cycloalkyl.

20. The method of claim 16, wherein the compound is at least one of the following: 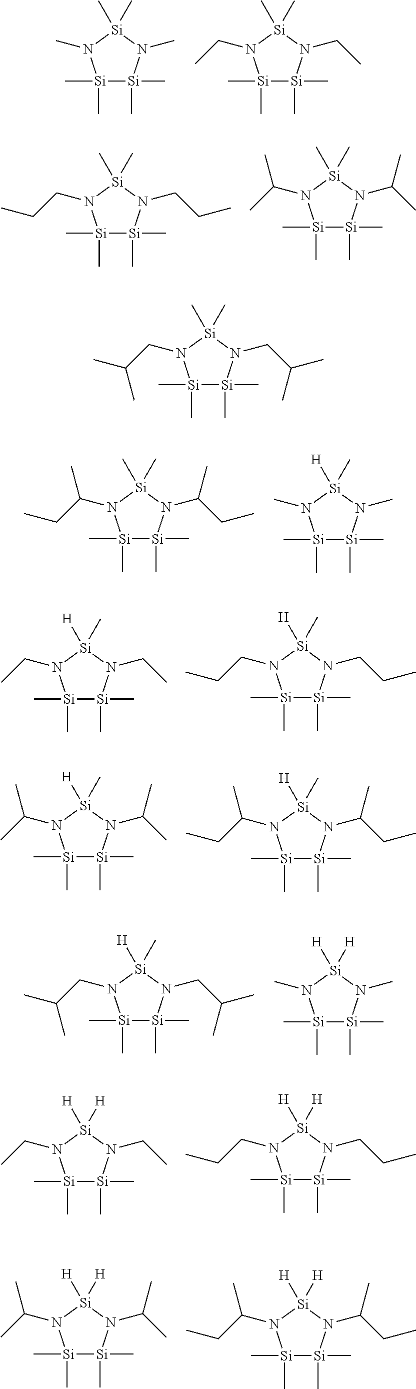 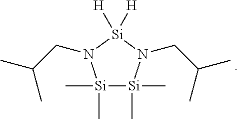 [SMILES: CC(C)CN1[SiH2]N(CC(C)C)[Si](C)(C)[Si]1(C)C]
